(19) United States
(12) Patent Application Publication
(10) Pub. No.: US 2025/0014954 A1
(43) Pub. Date: Jan. 9, 2025

(54) HYBRID CORES INCLUDING ADHESIVE PROMOTION LAYERS AND RELATED METHODS

(71) Applicants: Soham Agarwal, Chandler, AZ (US); Gang Duan, Chandler, AZ (US); Benjamin Duong, Phoenix, AZ (US); Darko Grujicic, Chandler, AZ (US); Kari Hernandez, Phoenix, AZ (US); Lei Jin, Chandler, AZ (US); Jesse Cole Jones, Chandler, AZ (US); Zheng Kang, Chandler, AZ (US); Shayan Kaviani, Phoenix, AZ (US); Yi Li, Chandler, AZ (US); Sandrine Lteif, Phoenix, AZ (US); Pratyush Mishra, Tempe, AZ (US); Mahdi Mohammadighaleni, Phoenix, AZ (US); Pratyasha Mohapatra, Hillsboro, OR (US); Logan Myers, Chandler, AZ (US); Suresh Tanaji Narute, Chandler, AZ (US); Srinivas Venkata Ramanuja Pietambaram, Chandler, AZ (US); Umesh Prasad, Chandler, AZ (US); Rengarajan Shanmugam, Tempe, AZ (US); Elham Tavakoli, Phoenix, AZ (US); Marcel Arlan Wall, Phoenix, AZ (US); Yekan Wang, Chandler, AZ (US); Ehsan Zamani, Phoenix, AZ (US)

(72) Inventors: Soham Agarwal, Chandler, AZ (US); Gang Duan, Chandler, AZ (US); Benjamin Duong, Phoenix, AZ (US); Darko Grujicic, Chandler, AZ (US); Kari Hernandez, Phoenix, AZ (US); Lei Jin, Chandler, AZ (US); Jesse Cole Jones, Chandler, AZ (US); Zheng Kang, Chandler, AZ (US); Shayan Kaviani, Phoenix, AZ (US); Yi Li, Chandler, AZ (US); Sandrine Lteif, Phoenix, AZ (US); Pratyush Mishra, Tempe, AZ (US); Mahdi Mohammadighaleni, Phoenix, AZ (US); Pratyasha Mohapatra, Hillsboro, OR (US); Logan Myers, Chandler, AZ (US); Suresh Tanaji Narute, Chandler, AZ (US); Srinivas Venkata Ramanuja Pietambaram, Chandler, AZ (US); Umesh Prasad, Chandler, AZ (US); Rengarajan Shanmugam, Tempe, AZ (US); Elham Tavakoli, Phoenix, AZ (US); Marcel Arlan Wall, Phoenix, AZ (US); Yekan Wang, Chandler, AZ (US); Ehsan Zamani, Phoenix, AZ (US)

(21) Appl. No.: 18/756,874

(22) Filed: Jun. 27, 2024

(51) Int. Cl. H01L 23/14; C08K 3/34; C09J 179/08; H01L 23/00; H01L 23/538

(52) U.S. Cl. CPC H01L 23/145; C09J 179/08; H01L 23/538; C08K 3/34; C09J 2400/143; C09J 2479/08; H01L 24/13; H01L 2224/16225

(57) ABSTRACT

Hybrid cores including adhesive promotion layers and related methods are disclosed. An example substrate core for an integrated circuit disclosed herein includes a frame including interior edge, a glass panel including an exterior edge, and an adhesion promotion layer disposed between the interior edge and the exterior edge.

### BACKGROUND

In many electronic devices, semiconductor chips and/or dies (e.g., integrated circuit (IC) chips) are connected to larger circuit boards such as motherboards and/or other types of printed circuit boards (PCBs). Frequently, the IC chips are contained IN a package that includes a package substrate with one or more redistribution layers containing metal interconnects that enable electrical connections between contacts on the IC chips and corresponding contacts on PCBs.

### BRIEF DESCRIPTION OF THE DRAWINGS

FIG. 1 is a cross-sectional side view of an example implementation of an integrated circuit (IC) package constructed in accordance of teachings of this disclosure.

FIG. 2 is a cross-sectional side view of an example hybrid core including an adhesive promoter layer implemented in accordance with teachings of this disclosure.

FIGS. 3, 4, and 5 are cross-sectional views depicting the hybrid core of FIG. 2 in various stages of a first manufacturing process.

FIGS. 6, 7, 8, and 9 are cross-sectional views depicting the hybrid core of FIG. 2 in various stages of a second manufacturing process.

FIG. 10 is a cross-sectional side view of another example hybrid core including an adhesive promoter layer implemented in accordance with teachings of this disclosure.

FIGS. 11 and 12 are cross-sectional views depicting the hybrid core of FIG. 10 in various stages of a manufacturing process.

FIG. 13 is a flowchart representative of an example manufacturing process for manufacturing the hybrid core of FIG. 2.

FIG. 14 is a flowchart representative of another example manufacturing process for manufacturing the hybrid core of FIG. 2.

FIG. 15 is a flowchart representative of an example manufacturing process for manufacturing the hybrid core of FIG. 10.

FIG. 16 is a top view of a wafer and dies that may be included in an IC package constructed in accordance with teachings disclosed herein.

FIG. 17 is a cross-sectional side view of an IC device that may be included in an IC package constructed in accordance with teachings disclosed herein.

FIG. 18 is a cross-sectional side view of an IC device assembly that may include an IC package constructed in accordance with teachings disclosed herein.

FIG. 19 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

In recent years, glass has been increasingly investigated as a core material for the package substrates of integrated circuit packages. The rigidness of glass cores reduces the warpage experience of glass cores and enables package substrates to have increased input/output density. Glass cores can be formed with tunable coefficients of thermal expansion, low total thickness variation, and tunable optical properties. While glass cores offer many advantages when compared to other core materials, the fragility of glass causes glass cores to be challenging to handle during manufacturing. For example, contact between the edges of the glass core and the tooling of fabrication machines can cause chipping and/or cracking of the glass core. In some such examples, stress applied to the glass core, such as the stress associated with the deposition of build-up layers on the glass cores, can cause cracks to propagate through the core. This cracking can cause the glass core to split (referred to herein as “seware”), which can result in the scrapping of the substrate package including the glass core during singulation.

Examples disclosed herein include package substrates that include hybrid cores and mitigate some of the above-noted challenges. Examples disclosed herein include hybrid cores that include glass panels positioned within a rigid frame. In some such examples disclosed herein, the frame increases the mechanical strength and resilience of the glass panels and acts as an interface between the glass panel and the tooling involved in the manufacturing of the integrated circuit package including the glass panel. Examples disclosed herein include adhesion promotion layers disposed between an exterior edge of the glass core and an interior edge of the frame. In some such examples disclosed herein, the adhesion promotion layer facilitates the bonding of the glass panel and the frame and reduces the likelihood of the separation thereof. Some example adhesion promotion layers disclosed herein include a resin-based and/or an epoxy-based polymer with a nanoparticle filler. Some adhesion promotion layers disclosed herein include shape memory polymers, such as a silicone elastomer, a thermoset epoxy-based polymer, polylactide, and/or ethylene-vinyl acetate. Some adhesion promotion layers disclosed herein include silicon nitride. Some adhesion promotion layer layers disclosed herein include amino-rich polymers, such as polyethylenimine. Some adhesion promotion layer layers disclosed herein include alkoxysilyl-functionalized epoxy materials.

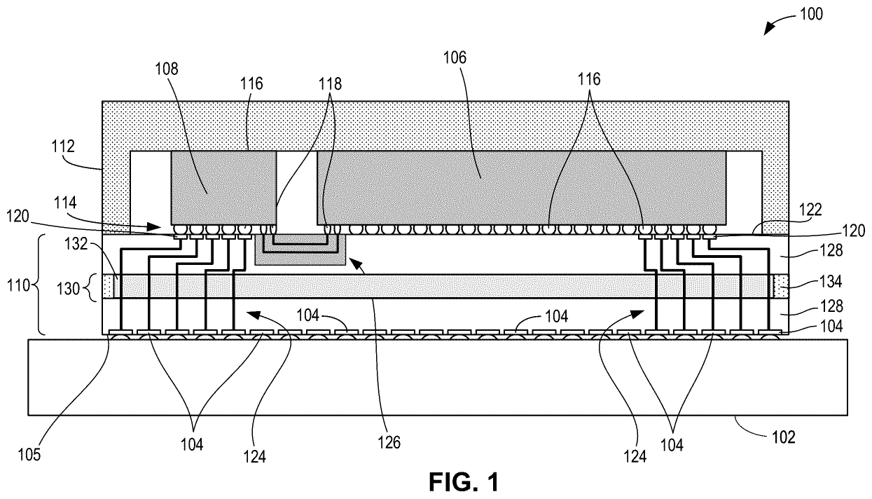

FIG. 1 illustrates an example integrated circuit (IC) package 100 constructed in accordance with teachings disclosed herein. In the illustrated example, the IC package 100 is electrically coupled to a circuit board 102 via an array of contact pads 104 (e.g., lands, etc.) on a mounting surface 105 (e.g., a bottom surface) of the package. In some examples, the IC package 100 may include balls, pins, and/or pads, in addition to or instead of the contact pads 104, to enable the electrical coupling of the IC package 100 to the circuit board 102. In this example, the IC package 100 includes an example first die 106 (e.g., a silicon die, a semiconductor die, etc.) and an example second die 108 that is mounted to a package substrate 110 and enclosed by a package lid 112 (e.g., a mold compound, etc.). Thus, the package substrate 110 is an example means for supporting a semiconductor die. While the example IC package 100 of FIG. 1 includes the dies 106, 108, in other examples, the IC package 100 may include additional dies. In some examples, some or all of the dies 106, 108, or a separate die are embedded in the package substrate 110. The dies 106, 108 can provide any suitable type of functionality (e.g., data processing, memory storage, etc.).

In the illustrated example of FIG. 1, the dies 106, 108 are electrically and mechanically coupled to the package substrate 110 via corresponding arrays of interconnects 114. In the illustrated example of FIG. 1, the interconnects 114 are bumps. In other examples, the interconnects 114 can be implemented any other type of electrical connection in addition to or instead of the bumps shown (e.g., balls, pins, pads, wire bonding, etc.). The electrical connections between the dies 106, 108 and the package substrate 110 (e.g., the interconnects 114, etc.) are referred to herein as “first level interconnects.” The electrical connections between the IC package 100 and the circuit board 102 (e.g., the contact pads 104, etc.) are referred to herein as “second level interconnects.” In some examples, one or both the dies 106, 108 are stacked on top of one or more other dies and/or an interposer. In some such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or between a die and an underlying die and/or interposer.

In the illustrated example of FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. That is, as shown in the illustrated example, when the dies 106, 108 are mounted to the package substrate 110, the core bumps 116 are physically connected and electrically coupled to contact pads 120 on an inner surface 122 of the package substrate 110. The contact pads 120 on the inner surface 122 of the package substrate 110 are electrically coupled to the contact pads 104 on the mounting surface 105 of the package substrate 110 (e.g., a surface opposite the inner surface 122, an external bottom surface, etc.) via internal interconnects 124 within the package substrate 110. As a result, there is a continuous electrical signal path between the interconnects 114 and the contacts pads 104 mounted to the circuit board 102 that pass through the contact pads 120 and the internal interconnects 124 provided therebetween.

As used herein, the bridge bumps 118 are bumps on the dies 106, 108 through which electrical signals pass between different ones of the dies 106, 108 within the IC package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

For purposes of illustration, the internal interconnects 124 are shown as straight lines extending directly between the contact pads 104 on the mounting surface 105 and the contact pads on the inner surface 122. However, in some examples, the internal interconnects 124 are defined by traces or routing in separate conductive (e.g., metal) layers within build-up regions 128 on one or both sides of a hybrid core 130 (e.g., the hybrid core, etc.) in the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the hybrid core 130.

In the illustrated example of FIG. 1, the substrate 110 of the example IC package 100 includes an example hybrid core 130. The example hybrid core 130 of FIG. 1 includes an example inner glass panel 132 supported, surrounded, and/or encapsulated by an example frame 134. In some examples, the inner glass panel 132 includes at least one of: aluminosilicate, borosilicate, alumino-borosilicate, silica, and/or fused silica. In some examples, the inner glass panel 132 includes one or more additives including: aluminum oxide (Al₂O₃), boron trioxide (B₂O₃), magnesia oxide (MgO), calcium oxide (CaO), stoichiometric silicon oxide (SiO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the inner glass panel 132 includes silicon and oxygen. In some examples, the inner glass panel 132 includes silicon, oxygen and/or one or more of aluminum, boron, magnesium, calcium, barium, tin, sodium, potassium, strontium, phosphorus, zirconium, lithium, titanium, and/or zinc. In some examples, the inner glass panel 132 includes at least 23 percent silicon by weight and at least 26 percent oxygen by weight. In some examples, the inner glass panel 132 is a layer of glass including silicon, oxygen, and aluminum. In some examples, the inner glass panel 132 includes at least 23 percent silicon by weight, at least 26 percent oxygen by weight, and at least 5 percent aluminum by weight. In some examples, the inner glass panel 132 is an amorphous solid glass layer. In some examples, the inner glass panel 132 is a layer of glass that does not include an organic adhesive or an organic material. In some examples, the inner glass panel 132 is a solid layer of glass having a rectangular shape in plan view. In some examples, the inner glass panel 132 includes at least one glass layer and does not include epoxy and does not include glass fibers (e.g., does not include an epoxy-based prepreg layer with glass cloth).

In some examples, the hybrid core 130 has a rectangular shape that is substantially coextensive, in plan view, with the layers (e.g., the build-up regions 128, etc.) above and/or below the core. In some examples, the hybrid core 130 has a thickness in a range of about 50 micrometers (μm) to about 3 millimeters (mm). In some examples, the inner glass panel 132 can be a multi-layer glass substrate (e.g., a coreless substrate), where a glass layer has a thickness in a range of about 25 μm to about 50 μm. In some examples, the hybrid core 130 has dimensions of about 10 mm on a side to about 250 mm on a side (e.g., 10 mm by 10 mm to 250 mm by 250 mm). In some examples, the hybrid core 130 corresponds to a rectangular prism volume with sections (e.g., vias) removed and filled with other materials (e.g., metal).

In some examples, the frame 134 supports the inner glass panel 132 and reinforces the hybrid core 130 to mitigate (e.g., reduce, prevent, etc.) potential damage to the hybrid core 130 during fabrication and/or packaging. In the illustrated example of FIG. 1, the frame 134 surrounds (e.g., encloses, etc.) the inner glass panel 132. That is, the frame 134 protects the inner glass panel 132 from shear stress, cracking, and/or any other damage from the mechanical handling of equipment during the fabrication of the IC package 100. In some examples, the frame 134 includes (e.g., is composed of, etc.) an organic material (e.g., an epoxy, a dielectric, a mold compound, etc.), a metal, and/or a copper clad laminate (CCL) frame.

In some examples, the different material compositions of the hybrid core 130 and the frame 134 can induce separation of the frame 134 and the hybrid core 130 due to mismatches in thermal expansion rate. That is, in some examples, the hybrid core 130 and the frame 134 have different coefficients of thermal expansion, which can cause separation, warpage, and other issues when the hybrid core 130 undergoes a large temperature change. Additionally or alternatively, stress (e.g., shear stress, etc.) applied to the hybrid core 130 during fabrication of the integrated circuit package 100 can cause the inner glass panel 132 to separate (e.g., delaminate, etc.) from the frame 134 and undergo seware. In some examples, delamination of the frame 134 and the inner glass panel 132 causes misalignment between components (e.g., vias, traces, etc.) routed through the hybrid core 130 and/or impeding the structural integrity of the IC package 100. In some examples, the frame 134 is removed after and/or during the fabrication of the integrated circuit package 100. Example cores disclosed herein include adhesion promotion layers to promote adhesion between the inner glass panel 132 and the frame 134 and to mitigate potential separation thereof.

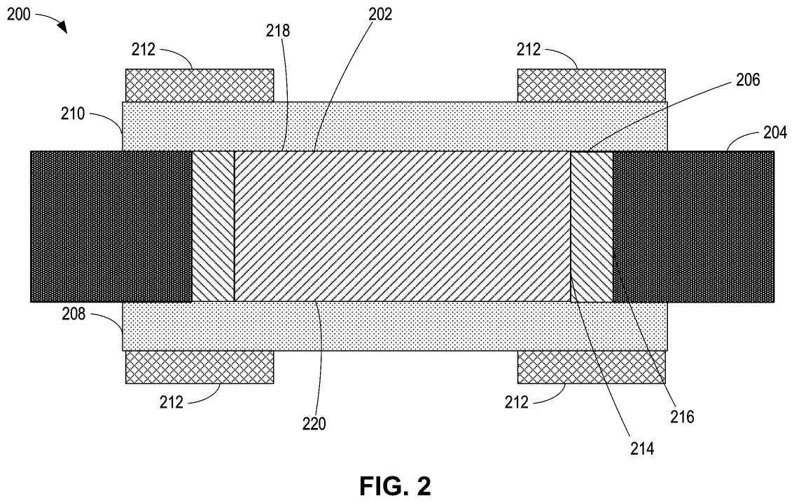

FIG. 2 is a cross-sectional side view of an example hybrid core 200 implemented in accordance with teachings of this disclosure. The hybrid core 200 can implement the hybrid core 130 of FIG. 1. In the illustrated example of FIG. 2, the hybrid core 200 includes an example inner glass panel 202, an example frame 204, an example adhesion promotion layer 206, an example first insulator layer 208, an example second insulator layer 210, and example glass-cloth phenolics (GCPs) 212.

The inner glass panel 202 is similar to the inner glass panel 132 of FIG. 1, unless noted otherwise. For example, the inner glass panel 202 can include (e.g., is composed of, etc.) a glass including silicon, oxygen, and/or aluminum. The frame 204 is similar to the frame 134 of FIG. 1 unless noted otherwise. The frame 204 supports and protects the inner glass panel 202 during the fabrication of the hybrid core 200 and/or the build-up on an integrated circuit package on the hybrid core 200 (e.g., the integrated circuit package 100 of FIG. 1, etc.). In some examples, the frame 204 includes (e.g., is composed of, etc.) an organic material (e.g., an epoxy, an organic polymer, etc.), a CCL, and/or a metal (e.g., aluminum, steel, a nickel-iron alloy, a nickel-iron-cobalt alloy, etc.).

The adhesion promotion layer 206, also referred to herein as “an adhesion promoter layer” and/or “an adhesion promoter,” promotes (e.g., facilitates, maintains, etc.) adhesion between the inner glass panel 202 and the frame 204. In the illustrated example of FIG. 2, the adhesion promotion layer 206 is coupled to an example exterior edge 214 of the inner glass panel 202 and an example interior edge 216 of the frame 204. In the illustrated example of FIG. 2, the adhesion promotion layer 206 extends between an example top surface 218 and an example bottom surface 220 of the inner glass panel 202 and/or frame 204. In the illustrated example of FIG. 2, the adhesion promotion layer 206 does not extend over the top surface 218 and/or the bottom surface 220 of the inner glass panel 202 and/or frame 204. In other examples, the adhesion promotion layer 206 extends over the top surface 218 of the inner glass panel 202. In the illustrated example of FIG. 2, the adhesion promotion layer 206 is between the inner glass panel 202 and the frame 204. In the illustrated example of FIG. 2, the adhesion promotion layer 206 is adjacent to and abuts the inner glass panel 202 and is adjacent to and abuts the frame 204. That is, the adhesion promotion layer 206 is in contact with the inner glass panel 202 and the frame 204. In other examples, one or more intermediate layer(s) can be disposed between the adhesion promotion layer 206 and the inner glass panel 202 and/or the adhesion promotion layer 206 and the frame 204.

In the illustrated example of FIG. 2, the adhesion promotion layer 206 includes a single discrete layer of material. In other examples, the adhesion promotion layer 206 can include multiple discrete material layers. For example, the adhesion promotion layer 206 can include a first layer abutting the inner glass panel 202 and a second layer abutting the frame 204. In some examples, the first layer of the adhesion promotion layer 206 is abutting the second layer of the adhesion promotion layer 206. In some such examples, the use of multiple layers in the adhesion promotion layer 206 can enable the adhesion promotion layer 206 to have different properties adjacent to the inner glass panel 202 (e.g., different electrical characteristics, different adhesive properties, different mechanical properties, different thermal expansion properties, etc.). An example adhesion promotion layer similar to the adhesion promotion layer 206 of FIG. 2 including multiple layers is described below in conjunction with FIG. 9.

The adhesion promotion layer 206 can be composed of any suitable adhesive material. For example, the adhesion promotion layer 206 can be composed of a resin and/or an epoxy material polymer. In some such examples, the adhesion promotion layer 206 can include one or more nanoparticle fillers to tune the mechanical properties, thermal properties, (e.g., thermal expansion coefficient, etc.), and/or electrical properties (e.g., electrical conductivity, etc.) of the adhesion promotion layer 206. For example, the adhesion promotion layer 206 can have a coefficient of thermal expansion that is equal to the coefficient of thermal expansion of the inner glass panel 202. In some such examples, the similar coefficients of thermal expansion (e.g., the equal coefficients of thermal expansion, etc.) between the adhesion promotion layer 206 and the inner glass panel 202 mitigate (e.g., reduce, prevent, etc.) warpage and/or cracking of the inner glass panel 202, etc.). In some examples, the adhesion promotion layer 206 has a similar (e.g., equal, etc.) elasticity as the inner glass panel 202 (e.g., a high Young's modulus, etc.), such that the adhesion promotion layer 206 is a stress buffer layer. In some examples, the adhesion promotion layer 206 can include nanoparticles (e.g., glass fibers, silica particles, alumina particles, etc.). That is, the adhesion promotion layer 206 can include a nanoparticle filler. Other example materials that can be included in the adhesion promotion layer 206 are described below.

In some examples, the adhesion promotion layer 206 includes an alkoxysilyl-functionalized epoxy material. For example, the adhesion promotion layer 206 can include alkoxysilyl-functionalized bisphenol A epoxy resin. In other examples, another alkoxysilyl-functionalized epoxy with high silica content (e.g., ˜85 weight %, etc.) can be used. In some such examples, the high silica content of the alkoxysilyl-functionalized epoxy causes the CTE of the epoxy to be approximately equal to glass (e.g., lower silica contexts are associated with higher CTEs, etc.). In some examples, the use of an alkoxysilyl-functionalized epoxy in the adhesion promotion layer 206 is suitable for managing comparatively large coefficient of thermal expansion (CTE) mismatches between the inner glass panel 202 and the frame 204. For example, the inclusion of an alkoxysilyl-functionalized epoxy in the adhesion promotion layer 206 can mitigate such CTE mismatches if the frame 204 includes (e.g., is composed of, etc.) a metal, such as aluminum (e.g., pure aluminum, an aluminum alloy, etc.), a steel, a nickel-iron alloy (e.g., 64FeNi, etc.), and/or a nickel-iron-cobalt alloy (e.g., Fernico I, etc.). In some examples, the alkoxysilyl-functionalized epoxy materials have coefficients of thermal expansion coefficients similar to the coefficients of thermal expansion to that of glass (e.g., 3.2 parts-per-million (ppm)/degree Celsius (C), etc.).

In some examples, the adhesion promotion layer 206 includes an amino-rich polymer. For example, the adhesion promotion layer 206 can include (e.g., be composed of, etc.) polymers including one or more amino (NH₂) functional groups, such as polyethylenimine (PEI) and polydiallyldimethylammonium chloride (polyDADMAC). In some such examples, the amino functional groups (NH₂) cause the polymers to be positively (e.g., cationic, etc.) charged, which encourages adhesion between the adhesion promotion layer 206 and the inner glass panel 202 and the adhesion promotion layer 206 and the frame 204 via electrostatic interactions (e.g., Van der Waals interactions, etc.). In some examples, the adhesion promotion layer 206 can form covalent bonds with the inner glass panel 202 and/or the frame 204. For example, the amino functional groups of the polymers can bond with reactive sites including hydrogen on exterior edge 216 of the inner glass panel 202. In some examples, the branching (e.g., the length of branches, the quantity of branches, etc.) of the amino-rich polymer can be tuned such that the adhesion promotion layer 206 has desired bonding characteristics with the inner glass panel 202 and/or a desired elasticity. The use of amino-rich polymers in the adhesion promotion layers 206 is suitable for frames 204 that are negatively charged (e.g., anionic, etc.) and/or otherwise attracted to charged materials (e.g., anionic organic materials, metals, etc.).

In some examples, the adhesion promotion layer 206 includes (e.g., is composed of, etc.) silicon nitride (SiN). For example, the adhesion promotion layer 206 can include Si₃N₄ (Trisilicon tetranitride). In other examples, the adhesion promotion layer 206 includes a different silicon nitride (e.g., silicon tetraazide, etc.). In some examples, the silicon nitride of the adhesion promotion layer 206 is bonded to the inner glass panel 202. In some examples, the hybrid core 200 includes an additional material (e.g., an adhesive polymer, etc.) disposed between the silicon nitride and the frame 204. In other examples, the silicon nitride is directly in contact with the frame 204. An example core including an adhesion promotion layer having multiple layers including a silicon nitride layer is described below in conjunction with FIG. 9.

In some examples, the adhesion promotion layer 206 includes (e.g., composed of, etc.) a shape memory polymer, which has high elasticity (e.g., a low Young's modulus, etc.), high adhesiveness, is self-healing, and has shape memory characteristics, etc. In some such examples, the high elasticity of the adhesion promotion layer 206 causes the adhesion promotion layer to absorb stress induced by thermal expansion mismatches between the inner glass panel 202 and the frame 204. In some such examples, the shape memory qualities of the adhesion promotion layer 206 counteract potential warpage associated with thermal expansion mismatches of the inner glass panel 202 and the frame 204. In some examples, the high elasticity of the adhesion promotion layer 206 maintains adhesion of the inner glass panel 202 and the frame 204 while under stress by facilitation of the elastic deformation of the adhesion promotion layer 206 in response to relative movement of the frame 204 and the inner glass panel 202 during fabrication of the hybrid core 200. In some such examples, because the polymers of the adhesion promotion layer 206 have shape-memory characteristics, the adhesion promotion layer 206 is self-healing. That is, the adhesion promotion layer 206 can revert from plastic deformation and/or separation of the internal chemical structure of the adhesion promotion layer 206 that can occur during the fabrication of the hybrid core 200. Example shape memory polymers that can be used in the adhesion promotion layer 206 include silicone elastomers, thermoset epoxy-based polymers, polylactide, ethylene-vinyl acetate, polyurethane, polylactic acid, and poly(methyl methacrylate-co-n-butyl acrylate).

The insulator layers 208, 210 are disposed on the top surface 218 and the bottom surface 220 of the inner glass panel 202. In some examples, the insulator layers 208, 210 include (e.g., are composed of, etc.) a dielectric material. For example, the insulator layers 208, 210 can include (e.g., are composed of, are, etc.) Ajinomoto build-up film (ABF). Additionally or alternatively, the insulator layers 208, 210 include different materials. In the illustrated example of FIG. 2, the insulator layers 208, 210 extend partially over the frame 204. In other examples, the insulator layers 208, 210 fully extend over the frame 204. In other examples, the insulator layers 208, 210 are only on the inner glass panel 202. In some such examples, the frame 204 can be removed after the fabrication of the integrated circuit package (e.g., the integrated circuit package 100, etc.). In other examples, one or both of the insulator layers 208, 210 are absent.

The GCPs 212 are mechanical isolators that protect the hybrid core 200 during the fabrication of the package substrate 110 of FIG. 1 and the deposition of components thereon. For example, the GCPs 212 can isolate the inner glass panel 202 during hard mechanical agitation and/or mechanical drift of the tooling used in the manufacturing of the package substrate 110 (e.g., the patterning of vias therethrough, etc.). In the illustrated example of FIG. 2, the hybrid core 200 includes four of the GCPs 212. In other examples, the hybrid core 200 includes a different quantity of GCPs 212. For example, the hybrid core 200 can include two of the GCPs 212, which are positioned in the center of one or both of the surfaces 218, 220. In some such examples, the GCPs 212 are absent. In some examples, some or all of GCPs can be implemented by a resin-coated copper (RCC) laminate.

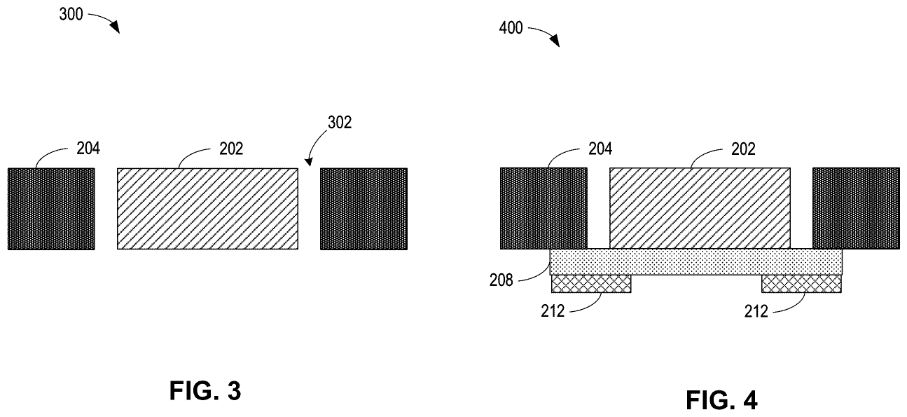

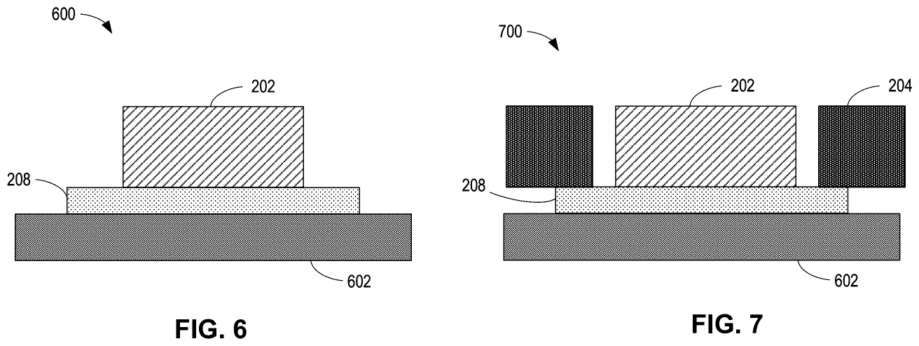

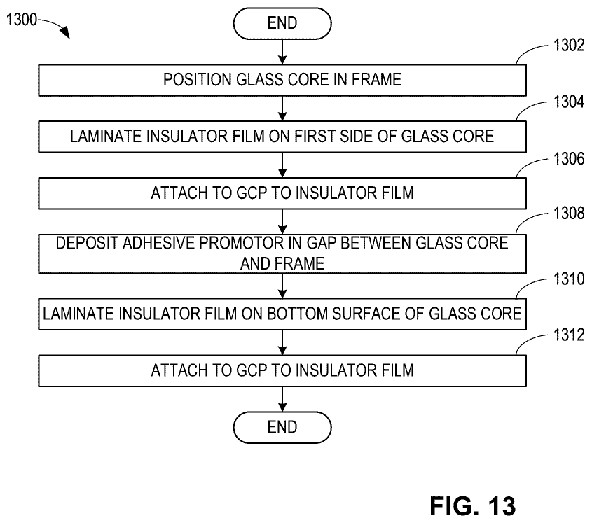

FIGS. 3, 4, and 5 depict a plurality of intermediate stages in an example process to manufacture the hybrid core 200 of FIG. 2. It should be appreciated that other processes and/or intermediate stages can be used to manufacture the hybrid core 200 of FIG. 2. In some examples, the intermediate stages of FIGS. 3, 4, and 5 are suitable for depositing the adhesion promotion layer 206 in a liquid and/or gel form. For example, the intermediate stages of FIGS. 3, 4, and 5 can be used to create a hybrid core including an adhesion promotion layer 206 that includes amino-rich polymers, shape memory polymers, nanoparticle-enriched polymers, and/or other polymer adhesives. Other intermediate stages that can be used to manufacture the glass core of FIG. 2 are described below in conjunction with FIGS. 6-9. Example operations to manufacture the hybrid core 200 of FIG. 2 via the intermediate stages of FIGS. 3, 4, and 5 are described below in conjunction with FIG. 13.

FIG. 3 is a cross-sectional schematic view of an example first intermediate stage 300 of the assembly/manufacturing of the hybrid core 200 of FIG. 2. During the first intermediate stage 300, the inner glass panel 202 is positioned within the frame 204. For example, the inner glass panel 202 can be mechanically positioned (e.g., via pick and place, etc.) within the frame 204. In other examples, the frame 204 is placed around the inner glass panel 202. In some such examples, the frame 204 is mechanically (e.g., via pick and place, etc.) positioned around the frame 204. In some examples, the inner glass panel 202 and/or the frame 204 is supported by a carrier (not illustrated). In the illustrated example of FIG. 3, the relative positioning of the inner glass panel 202 and the frame 204 creates an example gap 302 between the exterior edge 214 of the inner glass panel 202 and interior edge 216 of the frame 204. In the illustrated example of FIG. 3, the gap 302 is equally spaced along the perimeters of the edges 214, 216. In other examples, the gap 302 has a variable width at different locations along the inner glass panel 202.

FIG. 4 is a cross-sectional schematic view of an example second intermediate stage 400 of the assembly/manufacturing of the hybrid core 200 of FIG. 2. In some examples, the second intermediate stage 400 can occur after the first intermediate stage 300 of FIG. 3. During the second intermediate stage 400, the first insulator layer 208 is deposited on the bottom surface 220. For example, the first insulator layer 208 can be deposited via thin film deposition (TFD). In other examples, the first insulator layer 208 can be deposited via another material deposited method (e.g., atomic layer deposition, chemical vapor deposition, physical vapor deposition, sputtering, plating, etc.). In the illustrated example, two of the GCPs 212 are coupled to the first insulator layer 208. For example, the GCPs 212 can be laminated onto the first insulator layer 208.

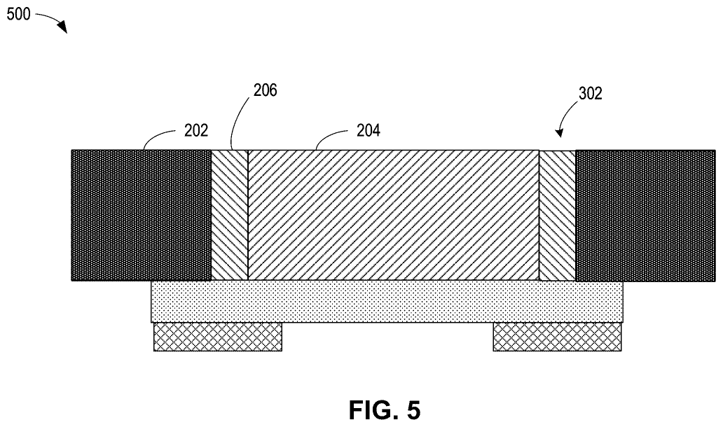

FIG. 5 is a cross-sectional schematic view of an example third intermediate stage 500 of the assembly/manufacturing of the hybrid core 200 of FIG. 2. In some examples, the third intermediate stage 500 can occur after the second intermediate stage 400 of FIG. 4. During the third intermediate stage 500, the adhesion promotion layer 206 is deposited in the gap 302. For example, the adhesion promotion layer 206 can be deposited in the gap 302 via inkjetting. In other examples, the adhesion promotion layer 206 is deposited via one or more other liquid and/or gel deposition methods (e.g., extrusion, sputtering, spin coating, etc.). In some examples, the adhesion promotion layers 206 can be annealed, cured, and/or otherwise hardened (e.g., heat cured, radiation cured, electron cured, etc.). In some examples, the treatment of the adhesion promotion layer 206 causes the adhesion promotion layer 206 to solidify (e.g., become a solid, become solid-like, etc.). In some examples, after the deposition of the adhesion promotion layer 206 during the third intermediate stage 500, the second insulator layer 210 and other ones of the GCPs 212 can be deposited on the top surface 218 of the inner glass panel 202 and the frame 204 to create the hybrid core 200 of FIG. 2.

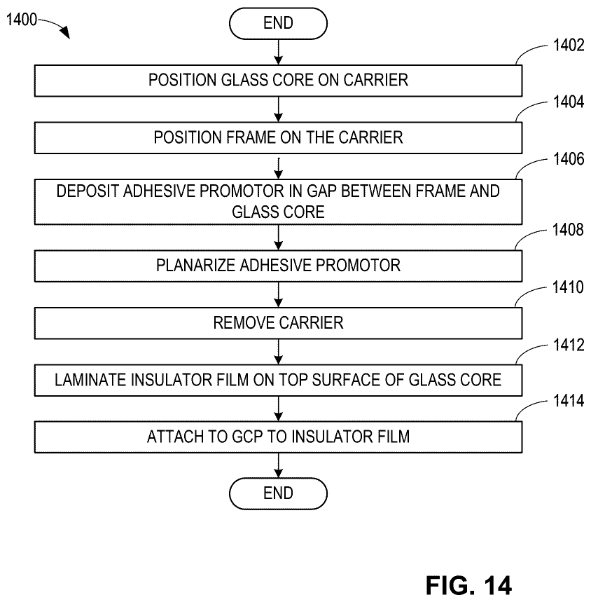

FIGS. 6, 7, 8, and 9 depict a plurality of intermediate stages in another example process to manufacture the hybrid core 200 of FIG. 2. It should be appreciated that other processes and/or intermediate stages can be used to manufacture the hybrid core 200 of FIG. 2. In some examples, the intermediate stages of FIGS. 6, 7, 8, and 9 are suitable for depositing the adhesion promotion layer 206 via a mold. For example, the intermediate stages of FIGS. 6, 7, 8, and 9 of an adhesion promotion layer 206 including am alkoxysilyl-functionalized epoxy. Example operations to manufacture the hybrid core 200 of FIG. 2 via the intermediate stages of FIGS. 6, 7, 8, and 9 are described below in conjunction with FIG. 14.

FIG. 6 is a cross-sectional schematic view of an example first intermediate stage 600 of the assembly/manufacturing of the hybrid core 200 of FIG. 2. During the first intermediate stage 600, the inner glass panel 202 of FIG. 2 is positioned on the second insulator layer 210 of FIG. 2 on an example carrier 602. In some examples, the carrier 602 can be implemented by any suitable rigid structure, such a polymer block, a composite block, a silicon wafer. In some examples, the first insulator layer 208 is deposited on the inner glass panel 202 prior to the positioning of the inner glass panel 202 on the carrier 602. In other examples, the first insulator layer 208 is laminated on the carrier 602 before the inner glass panel 202 is positioned thereon. In some examples, the inner glass panel 202 is mechanically positioned (e.g., via pick and place, etc.) on the carrier 602. In other examples, the inner glass panel 202 is fabricated on the carrier 602.

FIG. 7 is a cross-sectional schematic view of an example second intermediate stage 700 of the assembly/manufacturing of the hybrid core 200 of FIG. 2. In some examples, the second intermediate stage 700 can occur after the first intermediate stage 600 of FIG. 6. During the second intermediate stage 700, the frame 204 of FIG. 2 is placed around the inner glass panel 202 on the carrier 602 of FIG. 6. For example, the frame 204 can be mechanically positioned on (e.g., via pick and place, etc.) the carrier 602. In the illustrated example of FIG. 7, the relative positioning of the inner glass panel 202 and the frame 204 creates the gap 302 of FIG. 3 between the exterior edge 214 of the inner glass panel 202 and interior edge 216 of the frame 204. In the illustrated example of FIG. 7, the gap 302 is equally spaced along the perimeters of the edges 214, 216. In other examples, the gap 302 can have a variable width at different locations in the inner glass panel 202.

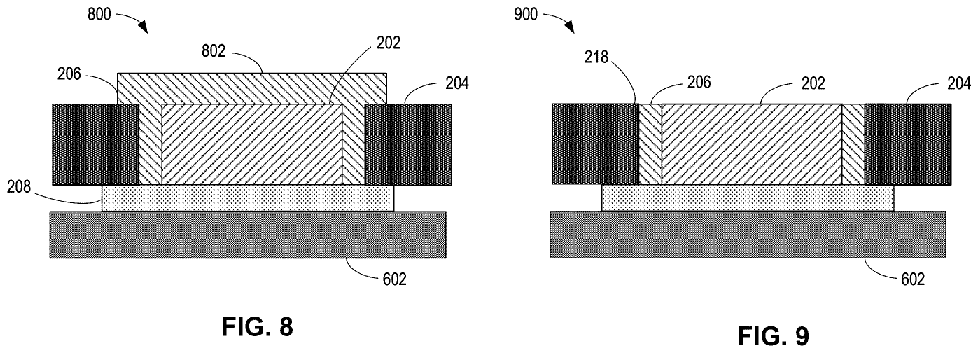

FIG. 8 is a cross-sectional schematic view of an example third intermediate stage 800 of the assembly/manufacturing of the hybrid core 200 of FIG. 2. In some examples, the third intermediate stage 800 can occur after the second intermediate stage 700 of FIG. 7. During the third intermediate stage 800, the adhesion promotion layer 206 is deposited in the gap 302 via molding. For example, the adhesion promotion layer 206 can be deposited in the gap 302 via injection molding (e.g., injection molding the adhesion promotion layer 206 into the area defined by the gap 302, casting the adhesion promotion layer 206, etc.). Additionally or alternatively, the adhesion promotion layer 206 is preformed (e.g., via molding, etc.) and mechanically disposed in the gap 302. In the illustrated example of FIG. 8, the deposition on the adhesion promotion layer 206 in the gap 302 during the third intermediate stage 800 causes an example material overflow 802 to occur on the top surface 218 of FIG. 2. For example, the material overflow 802 can occur as an overflow during the molding of the adhesion promotion layer 206.

FIG. 9 is a cross-sectional schematic view of an example fourth intermediate stage 900 of the assembly/manufacturing of the hybrid core 200 of FIG. 2. In some examples, the fourth intermediate stage 900 can occur after the third intermediate stage 800 of FIG. 8. During the fourth intermediate stage 900, the material overflow 802 of FIG. 8 is removed from the top surface 218 until the adhesion promotion layer 206 is flush with the top surface 218 of the inner glass panel 202 and the frame 204. In some examples, the material overflow 802 is removed via chemical-mechanical planarization, laser ablation, etching, and/or another suitable material removal process. In some examples, after the deposition of the adhesion promotion layer 206 during the fourth intermediate stage 900, the second insulator layer 210 is deposited on the top surface 218 of the inner glass panel 202, and/or the GCPs 212 are coupled to the insulator layers 208, 210 to create the hybrid core 200 of FIG. 2.

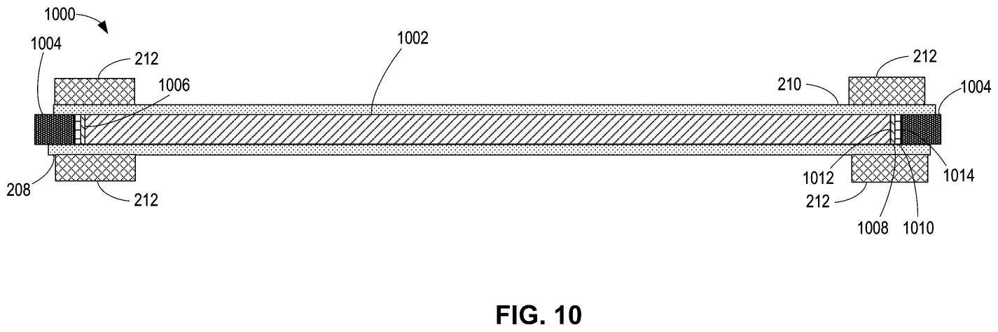

FIG. 10 is a cross-sectional side view of another example hybrid core 1000 implemented in accordance with teachings of this disclosure. In the illustrated example of FIG. 10, the hybrid core 1000 includes an example inner glass panel 1002, an example frame 1004, an example adhesion promotion layer 1006, which are similar to the inner glass panel 202 of FIG. 2, the frame 204 of FIG. 2, and the adhesion promotion layer 206 of FIG. 2, except as noted otherwise. For example, the inner glass panel 1002 can include (e.g., is composed of, etc.) a glass including silicon, oxygen, and aluminum. In some examples, the inner glass panel 1002 is a slightly smaller panel (SSP). The frame 1004 supports and protects the inner glass panel 1002 during the fabrication of the hybrid core 1000 and/or the build-up on an integrated circuit package on the hybrid core 1000 (e.g., the integrated circuit package 100 of FIG. 1, etc.). In the illustrated example of FIG. 10. In the illustrated example of FIG. 10, the hybrid core 1000 includes the insulator layers 208, 210 of FIG. 2.

Like the adhesion promotion layer 206 of FIG. 2, the adhesion promotion layer 1006 promotes (e.g., facilitates, maintains, etc.) adhesion between the inner glass panel 1002 and the frame 1004. In the illustrated example of FIG. 10, the adhesion promotion layer 1006 includes an example first layer 1008 and an example second layer 1010. In the illustrated example of FIG. 10, the first layer 1008 of the adhesion promotion layer 1006 is coupled to an example exterior edge 1012 of the inner glass panel 1002 and an example interior edge 1014 of the frame 1004. In the illustrated example of FIG. 10, the first layer 1008 is coupled to and abutting the second layer 1010. In the illustrated example of FIG. 10, the adhesion promotion layer 206 is between the inner glass panel 202 and the frame 204. In some examples, one or more intermediate layer(s) can be disposed between the first layer 1008 of the adhesion promotion layer 1006 and the glass inner panel 1002, the second layer 1008 of the adhesion promotion layer 1006 and the frame 1004, and the first layer 1008 and/or the second layer 1010.

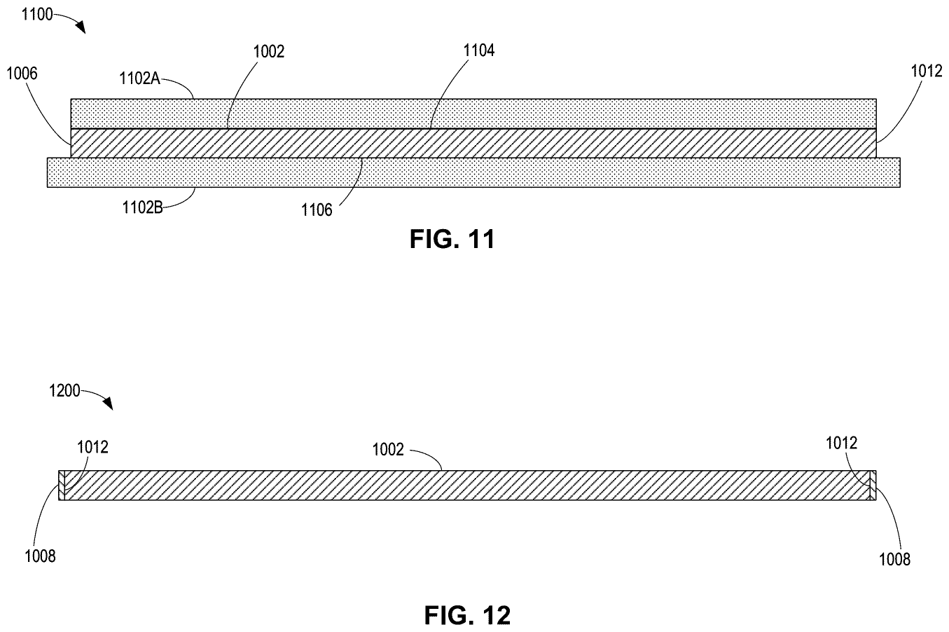

The first layer 1008 is coupled to the inner glass panel 1002. In some examples, the first layer 1008 is composed of silicon nitride (SiN). In other examples, the first layer 1008 can be composed of different materials that are adhesive to the inner glass panel 1002 and the second layer 1010. In some examples, the first layer 1008 is deposited on the exterior edge 1012 via physical vapor deposition, atomic layer deposition, chemical vapor deposition, and/or another thin layer deposition process. The deposition of the first layer 1008 on the exterior edge 1012 is described below in conjunction with FIGS. 11 and 12. In the illustrated example of FIG. 12, the second layer 1010 is coupled to the frame 1004. In some examples, the second layer 1010 can be implemented by one or more of the polymers described in conjunction with FIG. 2 (e.g., a nanoparticle enriched polymer, an amino-rich polymer, a shape memory polymer, alkoxysilyl-functionalized epoxy, etc.) and/or another adhesive polymer.

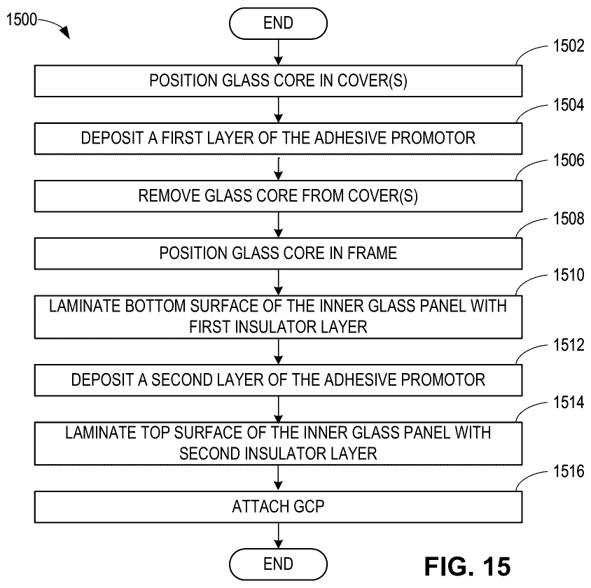

FIGS. 11 and 12 are cross-sectional views depicting the hybrid core 1000 of FIG. 10 in various intermediate stages of manufacture. It should be appreciated that other processes and/or intermediate stages can be used to manufacture the hybrid core 1000 of FIG. 10. In some examples, the intermediate stages of FIGS. 11 and 12 are suitable for depositing the first layer 1008 and/or the adhesion promotion layer 206 of FIG. 2 via physical vapor deposition (PVD), atomic layer deposition (ALD), and/or chemical vapor deposition (CVD). For example, the intermediate stages of FIGS. 11 and 12 are suitable for depositing an adhesion promotion layer including silicon nitride. Example operations to manufacture the hybrid core 1000 of FIG. 10 via the intermediate stages of FIGS. 11 and 12 are described below in conjunction with FIG. 15.

FIG. 11 is a cross-sectional schematic view of an example first intermediate stage 1100 of the assembly/manufacturing of the hybrid core 1000 of FIG. 10. During the first intermediate stage 1100, the inner glass panel 1002 is positioned between an example first cover 1102A and an examples second cover 1102B. For example, the hybrid core 1000 can be mechanically placed between the first cover 1102A and an example second cover 1102B. In other examples, the first cover 1102A and an example second cover 1102B are positioned around the inner glass panel 1002. The covers 1102A, 1102B are rigid components that are in contact with the inner glass panel 1002. In some examples, the covers 1102A, 1102B include (e.g., are composed of, etc.) CCL. In other examples, the covers 1102A, 1102B can be composed of any other suitable material that is not reactive with the precursors associated with the deposition process described below in conjunction with FIG. 12 (e.g., a material that is not reactive with the precursors used to form a layer of silicon nitride on the exterior edge 1012, etc.). In the illustrated example of FIG. 10, the relative position of the covers 1102A, 1102B, and the inner glass panel 1002 causes, the first cover 1102A to cover an example top surface 1104 of the inner glass panel 1002, the second cover 1102B to cover an example bottom surface 1106 of the inner glass panel 1002, and the exterior edge 1012 of the inner glass panel 1002 to be exposed.

FIG. 12 is a cross-sectional schematic view of an example second intermediate stage 1200 of the assembly/manufacturing of the hybrid core 1000 of FIG. 10. In some examples, the second intermediate stage 1200 can occur after the first intermediate stage 1100 of FIG. 11. During the second intermediate stage 1200, the first layer 1008 of the adhesion promotion layer 1006 has been deposited on the exterior edge 1012 of the adhesion promotion layer 1006. For example, the first layer 1008 can be deposited via atomic layer deposition, chemical vapor deposition, physical vapor deposition, and/or another deposition process. In some examples, the first layer 1008 of the adhesion promotion layer 1006 can be deposited via the reaction of a first precursor including silicon (e.g., silicon tetrachloride (SiCl₄), dichlorosilane (SiH₂Cl₂), hexachlorodisilane (Si₂Cl₆), octachlorotrisilane (Si₃Cl₈), etc.) and a second precursor including nitrogen (e.g., ammonia (NH₃), hydrazine (N₂H₄), etc.). In the illustrated example of FIG. 12, the covers 1102A, 1102B have been removed. For example, the covers 1102A, 1102B can be mechanically removed from the inner glass panel 1002. After the second intermediate stage 1200, the fabrication of the hybrid core 1000 of FIG. 10 can be completed via intermediate stages similar to the intermediate stages 300, 400, 500 of FIGS. 3-5 and/or the intermediate stages 600, 700, 800, 900 of FIGS. 6-9.

FIG. 13 is a block diagram of example operations 1300 for manufacturing a hybrid core 200 including an adhesion promotion layer 206 via the intermediate stages 300, 400, 500 of FIGS. 3-5. The operations 1300 begin at block 1302, at which the inner glass panel 202 of FIG. 2 is positioned within the frame 204 of FIG. 2. For example, the inner glass panel 202 can be mechanically (e.g., via pick and place, etc.) within the frame 204. In other examples, the frame 204 can be placed around the inner glass panel 202. In some examples, the inner glass panel 202 and/or the frame 204 can be positioned on a carrier (e.g., a carrier similar to the carrier 602 of FIG. 6, etc.). In some examples, the positioning of the inner glass panel 202 and the frame 204 creates an example gap 302 between the exterior edge 214 of the inner glass panel 202 and interior edge 216 of the frame 204. The point of fabrication after completion of block 1302 corresponds to the structure of the first intermediate stage 300 of FIG. 3.

At block 1304, the first insulator layer 208 is deposited on the bottom surface 220 of the hybrid core 200. For example, the first insulator layer 208 can be deposited as a layer of ABF. In some examples, the first insulator layer 208 can be deposited via lamination. Additionally or alternatively, the first insulator layer 208 can be deposited via thin film deposition. At block 1306, one or more of the GCPs 212 can be attached to the first insulator layer 208. For example, the GCPs 212 can be mechanically attached to the first insulator layer 208 (e.g., via pick and place, etc.). In other examples, the GCPs can be attached to the first insulator layer 208 via a different deposition technique. The point of fabrication after completion of block 1306 corresponds to the structure of the second intermediate stage 400 of FIG. 4.

At block 1308, the adhesion promotion layer 206 is deposited in the gap 302 between the inner glass panel 202 and the frame 204. For example, the adhesion promotion layer 206 can be deposited in the gap 302 via inkjetting. In other examples, the adhesion promotion layer 206 is deposited via one or more other liquid and/or gel deposition methods (e.g., extrusion, sputtering, spin coating, etc.). In some examples, the adhesion promotion layers 206 can be annealed, cured, and/or otherwise hardened (e.g., heat cured, radiation cured, electron cured, etc.). In some examples, the treatment of the adhesion promotion layer 206 causes the adhesion promotion layer 206 to solidify (e.g., become a solid, become solid-like, etc.). The point of fabrication after completion of block 1308 corresponds to the structure of the third intermediate stage 500 of FIG. 5.

At block 1310, the second insulator layer 210 is deposited on the top surface 218 of the hybrid core 200. For example, the second insulator layer 210 can be deposited as a layer of ABF. In some examples, the second insulator layer 210 can be deposited via lamination. Additionally or alternatively, the second insulator layer 210 can be deposited via thin film deposition. At block 1312, one or more of the GCPs 212 can be attached to the second insulator layer 210. For example, the GCPs 212 can be mechanically attached to the second insulator layer 210 (e.g., via pick and place, etc.). In other examples, the GCPs can be attached to the first insulator layer 208 via a different deposition technique. The operations 1300 end.

Although the example operations 1300 are described with reference to the flowchart illustrated in FIG. 13, many other methods of assembling/manufacturing the hybrid core 200 may alternatively be used. For example, alternative operations for the fabrication of the hybrid core 200 is described below in conjunction with FIG. 14. Additionally or alternatively, the order of execution of the blocks may be changed, and/or some of the blocks described may be changed, eliminated, or combined.

FIG. 14 is a block diagram of example operations 1400 for manufacturing a hybrid core 200 including an adhesion promotion layer 206 via the intermediate stages 600, 700, 800, 900 of FIGS. 6-9. The operations 1400 begin at block 1402, at which the inner glass panel 202 of FIG. 2 is positioned within the frame 204 of FIG. 2. For example, the inner glass panel 202 can be mechanically positioned on (e.g., via pick and place, etc.) the carrier 602 of FIG. 6. In some examples, the second insulator layer 210 of FIG. 2 is laminated on the inner glass panel 202 and/or the carrier 602 prior to the placement of the carrier 602. The point of fabrication after completion of block 1402 corresponds to the structure of the first intermediate stage 600 of FIG. 6.

At block 1404, the frame 204 of FIG. 2 is placed around the inner glass panel 202 on the carrier 602 of FIG. 6. For example, the frame 204 can be mechanically positioned on (e.g., via pick and place, etc.) the carrier 602. In the illustrated example of FIG. 7, the relative positioning of the inner glass panel 202 and the frame 204 creates the gap 302 of FIG. 3 between the exterior edge 214 of the inner glass panel 202 and interior edge 216 of the frame 204. In the illustrated example of FIG. 7, the gap 302 is equally spaced along the perimeters of the edges 214, 216. In other examples, the gap 302 has a variable width at different locations in the inner glass panel 202. The point of fabrication after completion of block 1404 corresponds to the structure of the second intermediate stage 700 of FIG. 7.

At block 1406, the adhesion promotion layer 206 is deposited in the gap 302 via molding. The adhesion promotion layer 206 can be deposited in the gap 302 via injection molding (e.g., injection molding the adhesion promotion layer 206 into the area defined by the gap 302, casting the adhesion promotion layer 206, etc.). Additionally or alternatively, the adhesion promotion layer 206 can be performed (e.g., via molding, etc.) and mechanically disposed in the gap 302. In the illustrated example of FIG. 8, the deposition on the adhesion promotion layer 206 in the gap 302 during the third intermediate stage 800 causes an example material overflow 802 to occur on the top surface 218 of FIG. 2. For example, the material overflow 802 can occur as an overflow during the molding of the adhesion promotion layer 206. The point of fabrication after completion of block 1406 corresponds to the structure of the third intermediate stage 800 of FIG. 8.

At block 1408, the material overflow 802 is removed from the top surface 218 until the adhesion promotion layer 206 is flush with the top surface 218 of the inner glass panel 202 and the frame 204. In some examples, the material overflow 802 is removed via chemical-mechanical planarization, laser ablation, etching, and/or another suitable material removal process. The point of fabrication after completion of block 1408 corresponds to the structure of the fourth intermediate stage 900 of FIG. 9.

At block 1410, the carrier 602 is removed from the inner glass panel 202. For example, the carrier 602 can be removed from the inner glass panel 202. At block 1412, the second insulator layer 210 is deposited on the top surface 218 of the hybrid core 200. For example, the second insulator layer 210 can be deposited as a layer of ABF. In some examples, the second insulator layer 210 can be deposited via lamination. Additionally or alternatively, the second insulator layer 210 can be deposited via thin film deposition. At block 1414, one or more of the GCPs 212 can be attached to the second insulator layer 210. For example, the GCPs 212 can be mechanically attached to the second insulator layer 210 (e.g., via pick and place, etc.). In other examples, the GCPs can be attached to the first insulator layer 208 via a different deposition technique. The operations 1400 end.

Although the example operations 1400 are described with reference to the flowchart illustrated in FIG. 14, many other methods of assembling/manufacturing the hybrid core 200 of FIG. 2 may alternatively be used. For example, the order of execution of the blocks may be changed, and/or some of the blocks described may be changed, eliminated, or combined.

FIG. 15 is a block diagram of example operations 1400 for manufacturing a hybrid core including the adhesion promotion layer 1006 of FIG. 10 via the intermediate stages 1100 and 1200 of FIGS. 11 and 12. The operations 1500 begin at block 1502 at which, the inner glass panel 1002 is positioned between the covers 1102A, 1102B of FIG. 11. For example, the hybrid core 1000 can be mechanically placed between the first cover 1102A and an example second cover 1102B. In other examples, the first cover 1102A and an example second cover 1102B are positioned around the inner glass panel 1002. In the illustrated example of FIG. 10, the relative position of the covers 1102A, 1102B, and the inner glass panel 1002 causes, the first cover 1102A to cover an example top surface 1104 of the inner glass panel 1002, the second cover 1102B to cover an example bottom surface 1106 of the inner glass panel 1002, and the exterior edge 1012 of the inner glass panel 1002 to be exposed. The point of fabrication after completion of block 1502 corresponds to the structure of the first intermediate stage 1100 of FIG. 11.

At block 1504, the first layer 1008 of the adhesion promotion layer 1006 has been deposited on the exterior edge 1012 of the adhesion promotion layer 1006. For example, the first layer 1008 can be deposited via atomic layer deposition, chemical vapor deposition, physical vapor deposition, and/or another deposition process. In some examples, the first layer 1008 of the adhesion promotion layer 1006 can be deposited via the reaction of a first precursor including silicon (e.g., silicon tetrachloride (SiCl₄), dichlorosilane (SiH₂Cl₂), hexachlorodisilane (Si₂Cl₆), octachlorotrisilane (Si₃Cl₈), etc.) and a second precursor including nitrogen (e.g., ammonia (NH₃), hydrazine (N₂H₄), etc.). At block 1506, the inner glass panel 1002 is removed from the covers 1102A, 1102B. For example, the inner glass panel 1002 is mechanically removed from the covers 1102A, 1102B. In other examples, the covers 1102A, 1102B can be mechanically removed from the inner glass panel 1002. The point of fabrication after completion of block 1506 corresponds to the structure of the first intermediate stage 1100 of FIG. 11.

At block 1508, the inner glass panel 1002 of FIG. 10 is positioned within the frame 1004 of FIG. 10. For example, the inner glass panel 1002 can be mechanically (e.g., via pick and place, etc.) within the frame 1004. In other examples, the frame 1004 can be placed around the inner glass panel 202. In some examples, the inner glass panel 1002 and/or the frame 1004 can be positioned on a carrier (e.g., a carrier similar to the carrier 602 of FIG. 6, etc.). At block 1510, the first insulator layer 208 is deposited on the bottom surface of the inner glass panel 1002. For example, the first insulator layer 208 can be deposited as a layer of ABF. In some examples, the first insulator layer 208 can be deposited via lamination. Additionally or alternatively, the first insulator layer 208 can be deposited via thin film deposition.

At block 1512, the second layer 1010 of the adhesion promotion layer 1006 is deposited. For example, the second layer 1010 of the adhesion promotion layer 1006 can be deposited between the first layer 1008 and the frame 1004 via inkjetting. In other examples, the second layer 1010 of the adhesion promotion layer 1006 is deposited via one or more other liquid and/or gel deposition methods (e.g., extrusion, sputtering, spin coating, etc.). Additionally or alternatively, the second layer 1010 of the adhesion promotion layer 1006 can be deposited via injection molding. Additionally or alternatively, the second layer 1010 of the adhesion promotion layer 1006 can be preformed (e.g., via molding, etc.) and mechanically disposed in the gap 302.

At block 1514, the second insulator layer 210 is deposited on the top surface 218 of the hybrid core 200. For example, the second insulator layer 210 can be deposited as a layer of ABF. In some examples, the second insulator layer 210 can be deposited via lamination. Additionally or alternatively, the second insulator layer 210 can be deposited via thin film deposition. At block 1516, one or more of the GCPs 212 can be attached to the second insulator layer 210. For example, the GCPs 212 can be mechanically attached to the second insulator layer 210 (e.g., via pick and place, etc.). In other examples, the GCPs can be attached to the first insulator layer 208 via a different deposition technique. The operations 1500 end.

Although the example operations 1500 are described with reference to the flowchart illustrated in FIG. 15, many other methods of assembling/manufacturing the hybrid core 1000 of FIG. 10 may alternatively be used. For example, the order of execution of the blocks may be changed, and/or some of the blocks described may be changed, eliminated, or combined.

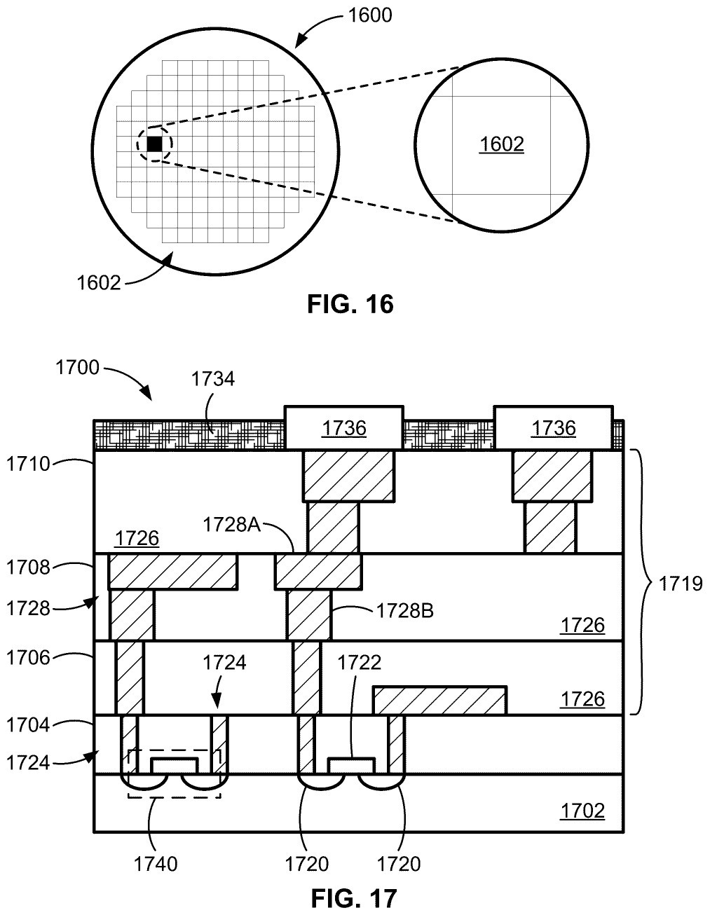

FIG. 16 is a top view of an example wafer 1600 and dies 1602 that may be included in the IC package 100 (e.g., as any suitable ones of the dies 106, 108, etc.). The wafer 1600 may be composed of semiconductor material and may include one or more dies 1602 having circuitry. Some or all of the dies 1602 may be a repeating unit of a semiconductor product. After the fabrication of the semiconductor product is complete, the wafer 1600 may undergo a singulation process in which the dies 1602 are separated from one another to provide discrete “chips.” One or more of the dies 1602 may include one or more transistors (e.g., some of the transistors 1740 of FIG. 17, discussed below), supporting circuitry to route electrical signals to the transistors, passive components (e.g., traces, resistors, capacitors, inductors, and/or other circuitry), and/or any other components. In some examples, the dies 1602 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die (e.g., a die of the dies 1602 of FIG. 16, etc.). For example, a memory array formed by multiple memory circuits may be formed on a same die (e.g., one of the dies 1602 of FIG. 16, etc.) as programmable circuitry or other logic circuitry. Such memory may store information for use by the programmable circuitry. The example IC package 100 disclosed herein may be manufactured using a die-to-wafer assembly technique in which the dies 106, 108, etc. are attached to a wafer 1600 that include others of the dies 106, 108, and the wafer 1600 is subsequently singulated.

FIG. 17 is a cross-sectional side view of an example IC device 1700 that may be included in the example IC package 100 (e.g., in any one of the dies 106, 108, etc.). One or more of the IC devices 1700 may be included in one or more dies 1602 (FIG. 16). The IC device 1700 may be formed on an example die substrate 1702 (e.g., the wafer 1600 of FIG. 16) and may be included in a die (e.g., a die of the dies 1602 of FIG. 16). The die substrate 1702 may be a semiconductor substrate composed of semiconductor material systems including, for example, n-type or p-type materials systems (or a combination of both). The die substrate 1702 may include, for example, a crystalline substrate formed using a bulk silicon or a silicon-on-insulator (SOI) substructure. In some examples, the die substrate 1702 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1702. Although a few examples of materials from which the die substrate 1702 may be formed are described here, any material that may serve as a foundation for an IC device 1700 may be used. The die substrate 1702 may be part of a singulated die (e.g., the dies 1602 of FIG. 16) or a wafer (e.g., the wafer 1600 of FIG. 16).

The IC device 1700 may include one or more example device layers 1704 disposed on or above the die substrate 1702. The device layer 1704 may include features of one or more example transistors 1740 (e.g., metal oxide semiconductor field-effect transistors (MOSFETs)) formed on the die substrate 1702. The device layer 1704 may include, for example, one or more example source and/or drain (S/D) regions 1720, an example gate 1722 to control current flow between the S/D regions 1720, and one or more example S/D contacts 1724 to route electrical signals to/from the S/D regions 1720. The transistors 1740 may include additional features not depicted for the sake of clarity such as, for example, device isolation regions, gate contacts, and the like. The transistors 1740 are not limited to the type and configuration depicted in FIG. 17 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 1740 may include an example gate 1722 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1740 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as, for example, a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1740 along the source-channel-drain direction, the gate electrode may include a U-shaped structure that includes a bottom portion substantially parallel to the surface of the die substrate 1702 and two sidewall portions that are substantially perpendicular to the top surface of the die substrate 1702. In other examples, at least one of the metal layers that form the gate electrode may be a planar layer that is substantially parallel to the top surface of the die substrate 1702 and does not include sidewall portions substantially perpendicular to the top surface of the die substrate 1702. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 1720 may be formed within the die substrate 1702 adjacent to the gate 1722 of respective ones of the transistors 1740. The S/D regions 1720 may be formed using an implantation/diffusion process or an etching/deposition process, for example. In the former process, dopants such as boron, aluminum, antimony, phosphorous, or arsenic may be ion-implanted into the die substrate 1702 to form the S/D regions 1720. An annealing process that activates the dopants and causes the dopants to diffuse farther into the die substrate 1702 may follow the ion-implantation process. In the latter process, the die substrate 1702 may first be etched to form recesses at the locations of the S/D regions 1720. An epitaxial deposition process may then be carried out to fill the recesses with material that is used to fabricate the S/D regions 1720. In some implementations, the S/D regions 1720 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1720 may be formed using one or more alternate semiconductor materials such as germanium or a group III-V material or alloy. In further examples, one or more layers of metal and/or metal alloys may be used to form the S/D regions 1720.

Electrical signals, such as power and/or input/output (I/O) signals, may be routed to and/or from the devices (e.g., transistors 1740) of the device layer 1704 through one or more example interconnect layers disposed on the device layer 1704 (illustrated in FIG. 17 as interconnect layers 1706-1710). For example, electrically conductive features of the device layer 1704 (e.g., the gate 1722 and the S/D contacts 1724) may be electrically coupled with example interconnect structures 1728 of the interconnect layers 1706-1710. The one or more interconnect layers 1706-1710 may form an example metallization stack (also referred to as an “ILD stack”) 1719 of the IC device 1700.

The interconnect structures 1728 may be arranged within the interconnect layers 1706-1710 to route electrical signals according to a wide variety of designs (in particular, the arrangement is not limited to the particular configuration of interconnect structures 1728 depicted in FIG. 17). Although a particular number of interconnect layers 1706-1710 is depicted in FIG. 17, examples of the present disclosure include IC devices having more or fewer interconnect layers than depicted.

In some examples, the interconnect structures 1728 may include example lines 1728A and/or example vias 1728B filled with an electrically conductive material such as a metal. The lines 1728A may be arranged to route electrical signals in a direction of a plane that is substantially parallel with a surface of the die substrate 1702 upon which the device layer 1704 is formed. For example, the lines 1728A may route electrical signals in a direction in and out of the page from the perspective of FIG. 17. The vias 1728B may be arranged to route electrical signals in a direction of a plane that is substantially perpendicular to the surface of the die substrate 1702 upon which the device layer 1704 is formed. In some examples, the vias 1728B may electrically couple lines 1728A of different interconnect layers 1706-1710 together.

The interconnect layers 1706-1710 may include an example dielectric material 1726 disposed between the interconnect structures 1728, as shown in FIG. 17. In some examples, the dielectric material 1726 disposed between the interconnect structures 1728 in different ones of the interconnect layers 1706-1710 may have different compositions. In other examples, the composition of the dielectric material 1726 between different interconnect layers 1706-1710 may be the same.

A first interconnect layer 1706 (referred to as Metal 1 or “M1”) may be formed directly on the device layer 1704. In some examples, the first interconnect layer 1706 may include lines 1728A and/or vias 1728B, as shown. The lines 1728A of the first interconnect layer 1706 may be coupled with contacts (e.g., the S/D contacts 1724) of the device layer 1704.

A second interconnect layer 1708 (referred to as Metal 2 or “M2”) may be formed directly on the first interconnect layer 1706. In some examples, the second interconnect layer 1708 may include vias 1728B to couple the lines 1728A of the second interconnect layer 1708 with the lines 1728A of the first interconnect layer 1706. Although the lines 1728A and the vias 1728B are structurally delineated with a line within each interconnect layer (e.g., within the second interconnect layer 1708) for the sake of clarity, the lines 1728A and the vias 1728B may be structurally and/or materially contiguous (e.g., simultaneously filled during a dual-damascene process) in some examples.

A third interconnect layer 1710 (referred to as Metal 3 or “M3”) (and additional interconnect layers, as desired) may be formed in succession on the second interconnect layer 1708 according to similar techniques and configurations described in connection with the second interconnect layer 1708 and/or the first interconnect layer 1706. In some examples, the interconnect layers that are “higher up” in the metallization stack 1719 in the IC device 1700 (i.e., further away from the device layer 1704) may be thicker.

The IC device 1700 may include an example solder resist material 1734 (e.g., polyimide or similar material) and one or more example conductive contacts 1736 formed on the interconnect layers 1706-1710. In FIG. 17, the conductive contacts 1736 are illustrated as taking the form of bond pads. The conductive contacts 1736 may be electrically coupled with the interconnect structures 1728 and configured to route the electrical signals of the transistor(s) 1740 to other external devices. For example, solder bonds may be formed on the one or more conductive contacts 1736 to mechanically and/or electrically couple a chip including the IC device 1700 with another component (e.g., a circuit board). The IC device 1700 may include additional or alternate structures to route the electrical signals from the interconnect layers 1706-1710; for example, the conductive contacts 1736 may include other analogous features (e.g., posts) that route the electrical signals to external components.

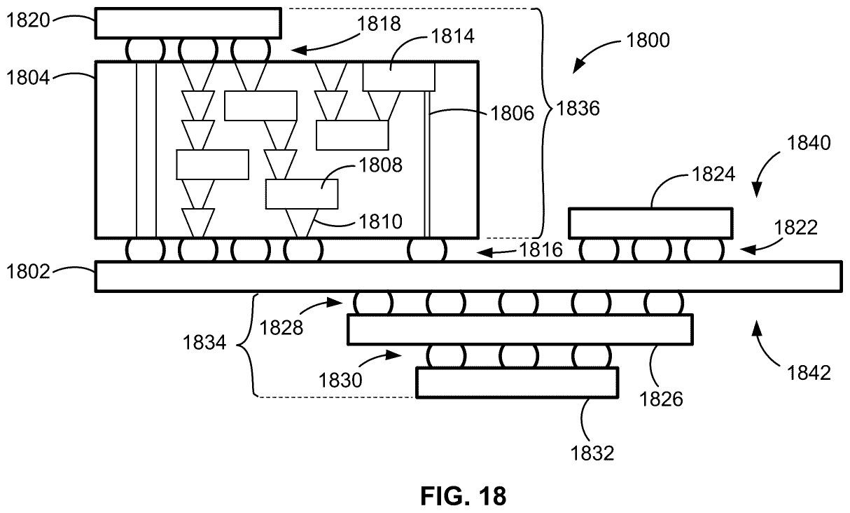

FIG. 18 is a cross-sectional side view of an example IC device assembly 1800 that may include the IC package 100 disclosed herein. In some examples, the IC device assembly corresponds to the IC package 100. The IC device assembly 1800 includes a number of components disposed on an example circuit board 1802 (which may be, for example, a motherboard). The IC device assembly 1800 includes components disposed on an example first face 1840 of the circuit board 1802 and an example opposing second face 1842 of the circuit board 1802. Any of the IC packages discussed herein with reference to the IC device assembly 1800 may take the form of the example IC package 100.

In some examples, the circuit board 1802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1802. In other examples, the circuit board 1802 may be a non-PCB substrate. In some examples, the circuit board 1802 may be, for example, the circuit board 102 of FIG. 1.

The IC device assembly 1800 illustrated in FIG. 18 includes an example package-on-interposer structure 1836 coupled to the first face 1840 of the circuit board 1802 by example coupling components 1816. The coupling components 1816 may electrically and mechanically couple the package-on-interposer structure 1836 to the circuit board 1802, and may include solder balls (as shown in FIG. 18), male and female portions of a socket, an adhesive, an underfill material, and/or any other suitable electrical, chemical, and/or mechanical coupling structure.

The package-on-interposer structure 1836 may include an example IC package 1820 coupled to an example interposer 1804 by example coupling components 1818. The coupling components 1818 may take any suitable form for the application, such as the forms discussed above with reference to the coupling components 1816. Although a single IC package 1820 is shown in FIG. 18, multiple IC packages may be coupled to the interposer 1804. Additionally or alternatively, in some examples, additional interposers may be coupled to the interposer 1804. The interposer 1804 may provide an intervening substrate used to bridge the circuit board 1802 and the IC package 1820. The IC package 1820 may be or include, for example, a die (e.g., a die of the dies 1602 of the dies of FIG. 16), an IC device (e.g., the IC device 1700 of FIG. 17), and/or any other suitable component(s). Generally, the interposer 1804 may spread a connection to a wider pitch or reroute a connection to a different connection. For example, the interposer 1804 may couple the IC package 1820 (e.g., a die) to a set of BGA conductive contacts of the coupling components 1816 for coupling to the circuit board 1802. In the example illustrated in FIG. 18, the IC package 1820 and the circuit board 1802 are attached to opposing sides of the interposer 1804. In other examples, the IC package 1820 and the circuit board 1802 may be attached to a same side of the interposer 1804. In some examples, three or more components may be interconnected by way of the interposer 1804.

In some examples, the interposer 1804 may be formed as a PCB, including multiple metal layers separated from one another by layers of dielectric material and interconnected by electrically conductive vias. In some examples, the interposer 1804 may be formed of an epoxy resin, a fiberglass-reinforced epoxy resin, an epoxy resin with inorganic fillers, a ceramic material, or a polymer material such as polyimide. In some examples, the interposer 1804 may be formed of alternate rigid or flexible materials that may include the same materials described above for use in a semiconductor substrate, such as silicon, germanium, and other group III-V and group IV materials. The interposer 1804 may include example metal interconnects 1808 and example vias 1810, including but not limited to example through-silicon vias (TSVs) 1806. The interposer 1804 may further include example embedded devices 1814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1804. The package-on-interposer structure 1836 may take the form of any of the package-on-interposer structures known in the art.

The IC device assembly 1800 may include an example IC package 1824 coupled to the first face 1840 of the circuit board 1802 by example coupling components 1822. The coupling components 1822 may take the form of any of the examples discussed above with reference to the coupling components 1816, and the IC package 1824 may take the form of any of the examples discussed above with reference to the IC package 1820.

The IC device assembly 1800 illustrated in FIG. 18 includes an example package-on-package structure 1834 coupled to the second face 1842 of the circuit board 1802 by coupling components 1828. The package-on-package structure 1834 may include a first example IC package 1826 and a second example IC package 1832 coupled together by example coupling components 1830 such that the first IC package 1826 is disposed between the circuit board 1802 and the second IC package 1832. The coupling components 1828, 1830 may take the form of any of the examples of the coupling components 1816 discussed above, and the IC packages 1826, 1832 may take the form of any of the examples of the IC package 1820 discussed above.

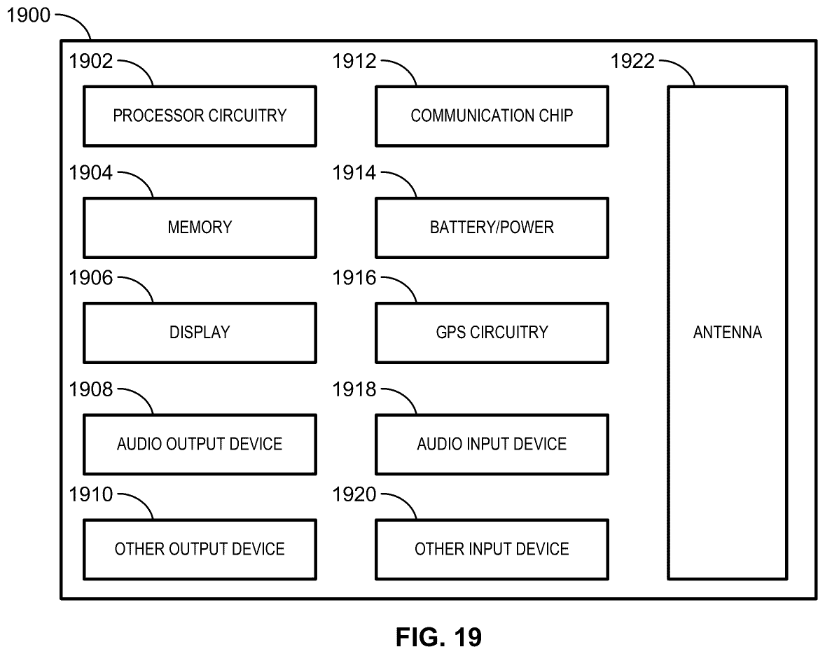

FIG. 19 is a block diagram of an example electrical device 1900 that may include one or more of the example IC package 100. For example, any suitable ones of the components of the electrical device 1900 may include one or more of the device assemblies 1800, IC devices 1700, or dies 1602 disclosed herein, and may be arranged in the example IC package 100. A number of components are illustrated in FIG. 19 as included in the electrical device 1900, but any one or more of these components may be omitted or duplicated, as suitable for the application. In some examples, some or all of the components included in the electrical device 1900 may be attached to one or more motherboards. In some examples, some or all of these components are fabricated onto a single system-on-a-chip (SoC) die.

Additionally, in some examples, the electrical device 1900 may not include one or more of the components illustrated in FIG. 19, but the electrical device 1900 may include interface circuitry for coupling to the one or more components. For example, the electrical device 1900 may not include an example display 1906, but may include display interface circuitry (e.g., a connector and driver circuitry) to which the display 1906 may be coupled. In some examples, the electrical device 1900 may not include an example audio input device 1918 (e.g., microphone) or an example audio output device 1908 (e.g., a speaker, a headset, earbuds, etc.), but may include audio input or output device interface circuitry (e.g., connectors and supporting circuitry) to which the audio input device 1918 or the audio output device 1908 may be coupled.

The electrical device 1900 may include example programmable or processor circuitry 1902 (e.g., one or more processing devices). The processor circuitry 1902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1900 may include an example memory 1904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1904 may include memory that shares a die with the processor circuitry 1902. This memory may be used as cache memory and may include embedded dynamic random access memory (eDRAM) or spin transfer torque magnetic random access memory (STT-MRAM).

In some examples, the electrical device 1900 may include an example communication chip 1912 (e.g., one or more communication chips). For example, the communication chip 1912 may be configured for managing wireless communications for the transfer of data to and from the electrical device 1900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1912 may operate in accordance with other wireless protocols in other examples. The electrical device 1900 may include an example antenna 1922 to facilitate wireless communications and/or to receive other wireless communications (such as AM or FM radio transmissions).

In some examples, the communication chip 1912 may manage wired communications, such as electrical, optical, or any other suitable communication protocols (e.g., the Ethernet). As noted above, the communication chip 1912 may include multiple communication chips. For instance, a first communication chip 1912 may be dedicated to shorter-range wireless communications such as Wi-Fi or Bluetooth, and a second communication chip 1912 may be dedicated to longer-range wireless communications such as global positioning system (GPS), EDGE, GPRS, CDMA, WiMAX, LTE, EV-DO, or others. In some examples, a first communication chip 1912 may be dedicated to wireless communications, and a second communication chip 1912 may be dedicated to wired communications.

The electrical device 1900 may include example battery/power circuitry 1914. The battery/power circuitry 1914 may include one or more energy storage devices (e.g., batteries or capacitors) and/or circuitry for coupling components of the electrical device 1900 to an energy source separate from the electrical device 1900 (e.g., AC line power).

The electrical device 1900 may include the display 1906 (or corresponding interface circuitry, as discussed above). The display 1906 may include any visual indicators, such as a heads-up display, a computer monitor, a projector, a touchscreen display, a liquid crystal display (LCD), a light-emitting diode display, or a flat panel display.

The electrical device 1900 may include the audio output device 1908 (or corresponding interface circuitry, as discussed above). The audio output device 1908 may include any device that generates an audible indicator, such as speakers, headsets, or earbuds.

The electrical device 1900 may include the audio input device 1918 (or corresponding interface circuitry, as discussed above). The audio input device 1918 may include any device that generates a signal representative of a sound, such as microphones, microphone arrays, or digital instruments (e.g., instruments having a musical instrument digital interface (MIDI) output).

The electrical device 1900 may include example GPS circuitry 1916. The GPS circuitry 1916 may be in communication with a satellite-based system and may receive a location of the electrical device 1900, as known in the art.

The electrical device 1900 may include any other example output device 1910 (or corresponding interface circuitry, as discussed above). Examples of the other output device 1910 may include an audio codec, a video codec, a printer, a wired or wireless transmitter for providing information to other devices, and/or an additional storage device.

The electrical device 1900 may include any other example input device 1920 (or corresponding interface circuitry, as discussed above). Examples of the other input device 1920 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1900 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve adhesion between glass cores and frames disposed therearound.

Disclosed systems, apparatus, articles of manufacture, and methods are accordingly directed to one or more improvement(s) in the operation of a machine such as a computer or other electronic and/or mechanical device. Example cores disclosed herein include adhesion promotion layers to promote adhesion between the inner glass panels and the frames and to mitigate potential separation thereof. Example adhesion promotion layers disclosed herein include mitigate potential seware and related delamination associated with prior hybrid cores.

Hybrid cores including adhesive promotion layers and related methods are disclosed. Further examples and combinations thereof include the following:

Example 1 includes a substrate core for an integrated circuit, the substrate core comprising a frame including an interior edge, a glass panel including an exterior edge, and an adhesion promotion layer disposed between the interior edge and the exterior edge.

Example 2 includes the substrate core of example 1, wherein the adhesion promotion layer includes a shape memory polymer.

Example 3 includes the substrate core of example 2, wherein the shape memory polymer includes at least one of a silicone elastomer, a thermoset epoxy-based polymer, a polylactide, or an ethylene-vinyl acetate.

Example 4 includes the substrate core of example 1, wherein the adhesion promotion layer includes a polymer with a nanoparticle filler.

Example 5 includes the substrate core of example 1, wherein the adhesion promotion layer includes silicon nitride.

Example 6 includes the substrate core of example 1, wherein the adhesion promotion layer includes an amino-rich polymer.

Example 7 includes the substrate core of example 6, wherein the amino-rich polymer is polyethylenimine.

Example 8 includes the substrate core of example 1, wherein the glass panel has a first coefficient of thermal expansion and the adhesion promotion layer has a second coefficient of thermal expansion approximately equal to the first coefficient of thermal expansion.

Example 9 includes the substrate core of example 1, wherein the adhesion promotion layer includes an alkoxysilyl-functionalized epoxy.

Example 10 includes the substrate core of any one examples 1-9, wherein the adhesion promotion layer extends between a top surface of the glass panel and a bottom surface of the glass panel.

Example 11 includes an integrated circuit package including a substrate core including an inner glass panel, a frame surrounding the inner glass panel, and an adhesion promotion layer coupling the inner glass panel to the frame, and a die mounted on the substrate core.

Example 12 includes the integrated circuit package of example 11, wherein the adhesion promotion layer includes a shape memory polymer.

Example 13 includes the integrated circuit package of example 12, wherein the shape memory polymer includes at least one of a silicone elastomer, a thermoset epoxy-based polymer, a polylactide, or an ethylene-vinyl acetate.

Example 14 includes the integrated circuit package of example 11, wherein the adhesion promotion layer includes a polymer with a nanoparticle filler.

Example 15 includes the integrated circuit package of example 11, wherein the adhesion promotion layer includes a first layer adjacent to an exterior edge of the inner glass panel, and a second layer adjacent to an interior edge of the frame.

Example 16 includes the integrated circuit package of example 15, wherein the first layer includes silicon nitride and the second layer includes an adhesive polymer.

Example 17 includes the integrated circuit package of example 11, wherein the adhesion promotion layer includes an amino-rich polymer.

Example 18 includes the integrated circuit package of example 17, wherein the amino-rich polymer is polyethylenimine.

Example 19 includes the integrated circuit package of example 11, wherein the adhesion promotion layer includes an alkoxysilyl-functionalized epoxy.

Example 20 includes the integrated circuit package of any one examples 11-19, wherein the adhesion promotion layer extends between a top surface of the inner glass panel and a bottom surface of the inner glass panel.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A substrate core for an integrated circuit, the substrate core comprising:
a frame including an interior edge;
a glass panel including an exterior edge; and
an adhesion promotion layer disposed between the interior edge and the exterior edge.

2. The substrate core of claim 1, wherein the adhesion promotion layer includes a shape memory polymer.

3. The substrate core of claim 2, wherein the shape memory polymer includes at least one of a silicone elastomer, a thermoset epoxy-based polymer, a polylactide, or an ethylene-vinyl acetate.

4. The substrate core of claim 1, wherein the adhesion promotion layer includes a polymer with a nanoparticle filler.

5. The substrate core of claim 1, wherein the adhesion promotion layer includes silicon nitride.

6. The substrate core of claim 1, wherein the adhesion promotion layer includes an amino-rich polymer.

7. The substrate core of claim 6, wherein the amino-rich polymer is polyethylenimine.

8. The substrate core of claim 1, wherein the glass panel has a first coefficient of thermal expansion and the adhesion promotion layer has a second coefficient of thermal expansion approximately equal to the first coefficient of thermal expansion.

9. The substrate core of claim 1, wherein the adhesion promotion layer includes an alkoxysilyl-functionalized epoxy.

10. The substrate core of claim 1, wherein the adhesion promotion layer extends between a top surface of the glass panel and a bottom surface of the glass panel.

11. An integrated circuit package including:
a substrate core including:
an inner glass panel;
a frame surrounding the inner glass panel; and
an adhesion promotion layer coupling the inner glass panel to the frame; and
a die mounted on the substrate core.

12. The integrated circuit package of claim 11, wherein the adhesion promotion layer includes a shape memory polymer.

13. The integrated circuit package of claim 12, wherein the shape memory polymer includes at least one of a silicone elastomer, a thermoset epoxy-based polymer, a polylactide, or an ethylene-vinyl acetate.

14. The integrated circuit package of claim 11, wherein the adhesion promotion layer includes a polymer with a nanoparticle filler.

15. The integrated circuit package of claim 11, wherein the adhesion promotion layer includes:
a first layer adjacent to an exterior edge of the inner glass panel; and
a second layer adjacent to an interior edge of the frame.

16. The integrated circuit package of claim 15, wherein the first layer includes silicon nitride and the second layer includes an adhesive polymer.

17. The integrated circuit package of claim 11, wherein the adhesion promotion layer includes an amino-rich polymer.

18. The integrated circuit package of claim 17, wherein the amino-rich polymer is polyethylenimine.

19. The integrated circuit package of claim 11, wherein the adhesion promotion layer includes an alkoxysilyl-functionalized epoxy.

20. The integrated circuit package of claim 11, wherein the adhesion promotion layer extends between a top surface of the inner glass panel and a bottom surface of the inner glass panel.
